(19) United States
(12) Patent Application Publication
(10) Pub. No.: US 2007/0290344 A1
(43) Pub. Date: Dec. 20, 2007

(54) Printed circuit board for package of electronic components and manufacturing method thereof

(75) Inventors: Myung-Sam Kang, Suwon-si (KR); Byoung-Youl Min, Seongnam-si (KR); Joon-Sung Kim, Suwon-si (KR); Je-Gwang Yoo, Yongin-si (KR); Jong-Gyu Choi, Seoul (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 11/783,871

(22) Filed: Apr. 12, 2007

(30) Foreign Application Priority Data
Jun. 16, 2006 (KR) 10-2006-0054459

(51) Int. Cl. H01L 23/488; H01L 21/44

(52) U.S. Cl. 257/738; 438/613; 257/E23.023; 257/E21.476

(57) ABSTRACT

The present invention relates to a printed circuit board, and in particular, to a printed circuit board for a package of electronic components and manufacturing method thereof. One aspect of present invention provides a manufacturing method of a printed circuit board for an electronic component package, which includes: forming a circuit pattern including bonding pads on one side of a first insulation layer, laminating a second insulation layer onto one side of the first insulation layer, and exposing the bonding pads by removing a part of the first insulation layer and the second insulation layer corresponding to the location in which the bonding pads is formed.

### CROSS-REFERENCE TO RELATED APPLICATIONS

This application claims the benefit of Korean Patent Application No. 2006-0054459 filed with the Korean Intellectual Property Office on Jun. 16, 2006, the disclosure of which is incorporated herein by reference in its entirety.

### BACKGROUND

1. Technical Field

The present invention relates to a printed circuit board, and in particular, to a printed circuit board for a package of electronic components and manufacturing method thereof.

2. Description of the Related Art

With developments in the electronics industry, the use of the memory packages mounted with memory chips in electronic devices is rapidly increasing. Moreover, companies manufacturing and supplying memory packages are also increasing, with companies expanding their business to fields concerning memory packages. In this competitive market situation, various plans have been suggested for decreasing costs.

Presently, in most cases, a memory package is implemented by making one package using wire bonding, as shown in FIGS. 1a, 1b, and this package is called a BOC (Board-on-chip). The BOC has been specially developed for the characteristics of the memory chip, and has the pads of the memory chip positioned at the center of a substrate, with the structure of pads positioned for connecting directly with the substrate. The BOC is a structure in which a slot is formed where the pads are positioned in order to attach the memory chip under the substrate, where wire bonding can be performed through the slot. Thus, the BOC requires only one metal layer, which gives it dominance in price competitiveness of the memory package.

However, with the very rapid developments in the technology of manufacturing semiconductors, the capacity of the memory package is also increasing. This creates a risk of signal losses at the wires in cases of using the conventional BOC.

### SUMMARY

An aspect of the present invention is to provide a printed circuit board for mounting an electronic component package and manufacture thereof that allow the mounting of a high-capacity memory chip.

Additional aspects and advantages of the present invention will become apparent and more readily appreciated from the following description, including the appended drawings and claims, or may be learned by practice of the invention.

One aspect of the present invention provides a manufacturing method of a printed circuit board for an electronic component package, which includes: forming a circuit pattern including bonding pads on one side of a first insulation layer, laminating a second insulation layer onto one side of the first insulation layer, and exposing the bonding pads by removing a part of the first insulation layer and the second insulation layer corresponding to the location in which the bonding pads are formed.

The circuit pattern may further include solder ball pads, and the exposing of the bonding pads may further comprise exposing the solder ball pads by removing the part of the first insulation layer or the part of the second insulation layer which correspond to the location of the solder ball pads.

The forming of a circuit pattern may further include laminating a seed layer onto a carrier board, forming the circuit pattern on the seed layer, laminating the first insulation layer onto the carrier board such that the circuit pattern is embedded in the first insulation layer, and removing the carrier board and the seed layer.

The first insulation layer and the second insulation layer may include a photoresist material, and the exposing of the bonding pads comprises removing the part of the first insulation layer and the part of the second insulation layer by exposure and development.

Another aspect of the present invention provides a printed circuit board for an electronic component package, which includes: a first insulation layer, a circuit pattern laminated on one side of the first insulation layer and comprising the bonding pads and the solder ball pads, a second insulation layer laminated on the one side of the first insulation layer, a cavity that is formed by removing a part of the first insulation layer and a part of the second insulation layer in correspondence to the location of the bonding pads and the solder ball pads for exposing the bonding pads and the solder ball pads.

The first insulation layer and the second insulation layer may be photosensitive.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1a is a perspective view of an electronic component package according to prior art.

FIG. 1b is a cross-sectional view of an electronic component package according to prior art.

FIG. 2 is a flowchart of a manufacturing method of a printed circuit board for an-electronic component package according to a first disclosed embodiment of the invention.

FIG. 3 is a fabrication diagram of a memory package according to the first disclosed embodiment of the invention.

FIG. 4 is a cross-sectional view of a printed circuit board for an electronic components package according to a second disclosed embodiment of the invention.

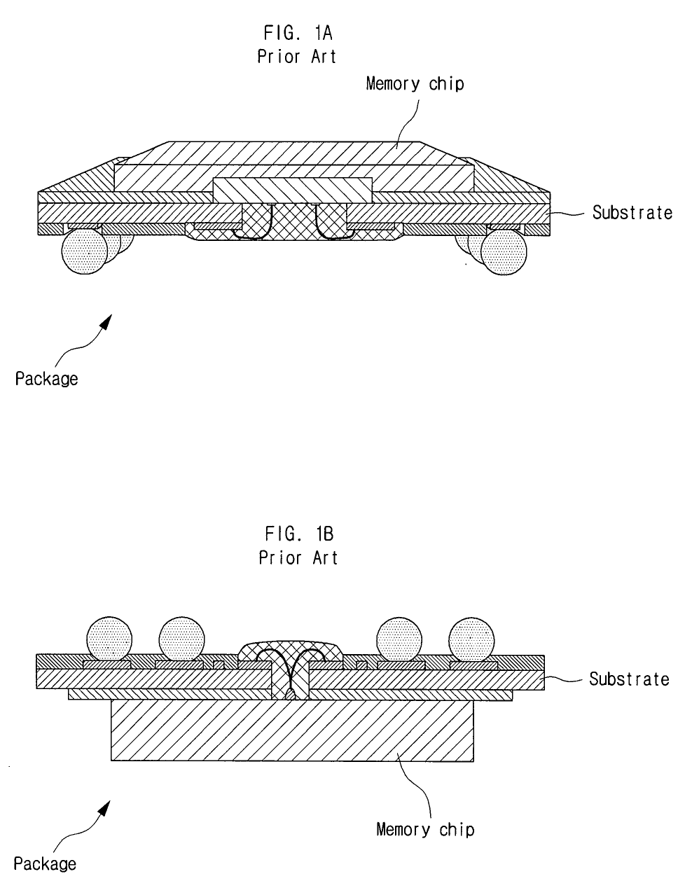

### DETAILED DESCRIPTION

Embodiments of the printed circuit board for the electronic component package and manufacturing thereof according to the invention will be described below in more detail with reference to the accompanying drawings. In the description with reference to the accompanying drawings, those components are rendered the same reference number that are the same or are in correspondence regardless of the figure number, and redundant explanations are omitted.

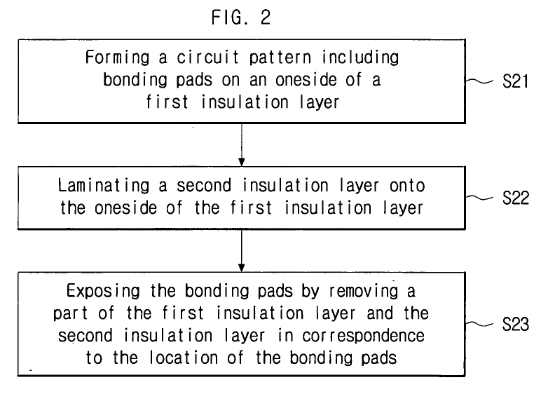

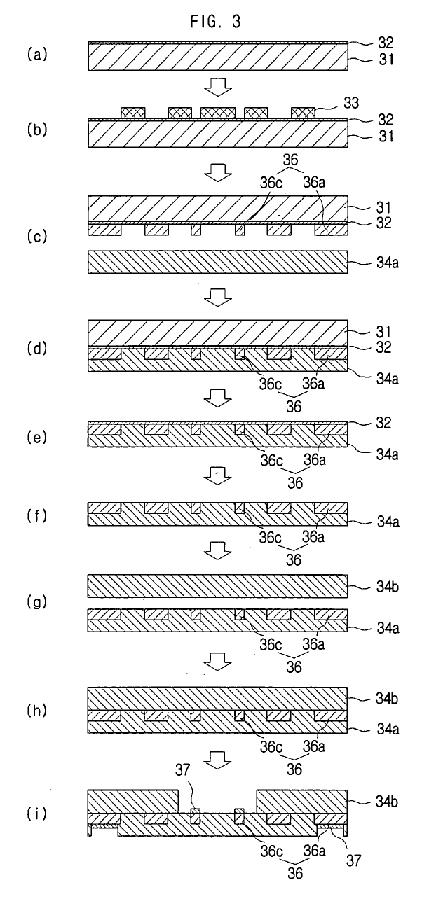

FIG. 2 is a flowchart of the manufacturing method of a printed circuit board for an electronic component package according to a first disclosed embodiment of the invention, and FIG. 3 is a fabrication diagram of the memory package according to the first disclosed embodiment of the invention. Referring to FIG. 3, a carrier board 31, a seed layer 32, a dry film 33, a first insulation layer 34a, a second insulation layer 34b, solder ball pads 36a, a circuit pattern 36, bonding pads 36c, and a plating layer 37 are illustrated.

S21 of FIG. 2 is the operation for forming the circuit pattern 36, which includes the bonding pads 36c and the solder ball pads 36a, on the first insulation layer 34a. Drawings (a) to (f) of FIG. 3 correspond to S21.

Drawing (a) of FIG. 3 describes the operation for laminating the seed layer 32 onto the carrier board 31. The seed layer 32 may be formed by electroless plating, but any material adhered with a thin copper foil may be used. Any material that allows ready detachment may be used as the carrier board 31.

Drawing (b) of FIG. 3 describes the process for laminating the dry film 33 onto the seed layer 32, and removing parts of the dry film 33, in which the circuit pattern 36 including the solder ball pads 36a and bonding pads 36c will be formed, through exposure and development processes. After electro plating and removing the dry film 33, the circuit pattern 36 including the bonding pads 36c and solder ball pads 36a is formed on the seed layer 32 as shown in FIG. 3.

Drawing (d) of FIG. 3 is the process for laminating the carrier board 31 on the first insulation layer 34a. At this time, the circuit pattern 36 is impregnated to the first insulation layer 34a as shown in FIG. 3.

Afterwards, the carrier board 31 and the seed layer 32 are removed as in (e) and (f) of FIG. 3, at which the buried pattern substrate 30 is complete. The buried pattern substrate 30 has an advantage that a semiconductor chip can be mounted easily, because the surface of the buried pattern substrate 30 is flat.

Various methods, besides the method shown in (a) to (f) of FIG. 3, may be applied for forming the buried pattern substrate in S21 of FIG. 2. For example, a subtractive method of forming a circuit pattern after removing the copper foil of a copper-clad laminate, or a semi-additive method of forming a circuit pattern after laminating a seed layer on the insulation layer may be used.

S22 of FIG. 2 is the operation for laminating the second insulation layer 34b onto the one side of the first insulation layer 34a. Drawings (g) and (h) of FIG. 3 describe process that are in correspondence to S22. The second insulation layer 34b is laminated onto the one side of the first insulation layer 34a on which the circuit pattern 36 has been impregnated as in (g) of FIG. 3. Consequently, the circuit pattern 36 including the bonding pads 36c and solder ball pads 36a is positioned between the first insulation layer 34a and the second insulation layer 34b, as in (i) of FIG. 3.

S23 of FIG. 2 is the operation for exposing the bonding pads 36 and solder ball pads 36a after removing a part of first insulation layer 34a and a part of second insulation layer 34b. The first insulation layer 34a and second insulation layer 34b may be made of photosensitive material, whereby the first insulation layer 34a and second insulation layer 34b can be removed after the exposure and development processes. As shown in (j) of FIG. 3, the solder ball pads 36a are exposed as a result of removing the first insulation layer 34a, and the bonding pads 36 are exposed after the second insulation layer 34b is removed. The bonding pads 36a are the parts where the semiconductor chip will be mounted, and the solder ball pads 36a are the parts where the solder balls will be adhered.

A surface treatment process may additionally be performed on the exposed solder ball pads 36a and the exposed bonding pads 36. The plating layer 37 is formed after the surface process is completed. The plating layer 37 is formed by gold plating after nickel plating.

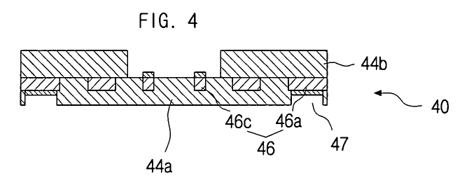

FIG. 4 is a cross-sectional view of the printed circuit board for an electronic component package according to a second disclosed embodiment. Referring to FIG. 4, a printed circuit board 40 for a package, a first insulation layer 44a, a second insulation layer 44b, solder ball pads 46a, a circuit pattern 46, bonding pads 46c, and a cavity 47 are illustrated.

As shown in FIG. 4, the printed circuit board 40 for a package according to this embodiment has the circuit pattern 46b including the solder ball pads 36a and the bonding pads 46c positioned on a single layer interposed between the first insulation layer 44a and the second insulation layer 44b.

The first insulation layer 44a and second insulation layer 44b may be made of photosensitive material, and parts of the first insulation layer 44a and the second insulation layer 44b are removed in order to expose the solder ball pads 46a and bonding pads 46c. The removal may be effected through exposure and development processes performed on the first photosensitive insulation layer 44a and second photosensitive insulation layer 44b. Meanwhile, the solder ball pads 46a and bonding pads 46c are exposed due to the forming of the cavity 47. Surface-treatment may be applied to the exposed solder ball pads 46a. The surface-treatment may be in the form of gold-plating over nickel-plating.

According to certain embodiments of the invention as described in the above, the length of the signal wire becomes shorter than in a conventional printed circuit board for an electronic component package and fast signal processing is possible. Also, it is possible to form high density circuits due to the use of the semi additive method. Moreover, because the circuit pattern layer is implemented as a single layer, superb heat releasing properties are obtained.

While the above description has pointed out novel features of the invention as applied to various embodiments, the skilled person will understand that various omissions, substitutions, and changes in the form and details of the device or process illustrated may be made without departing from the scope of the invention. Therefore, the scope of the invention is defined by the appended claims rather than by the foregoing description. All variations coming within the meaning and range of equivalency of the claims are embraced within their scope.

What is claimed is:

1. A manufacturing method of a printed circuit board for an electronic component package, the method comprising:
forming a circuit pattern including bonding pads on one side of a first insulation layer;
laminating a second insulation layer onto the one side of the first insulation layer; and
exposing the bonding pads by removing a part of the first insulation layer and the second insulation layer in correspondence with the location of the bonding pads.

2. The method of claim 1, wherein the circuit pattern further comprises solder ball pads, and the exposing of the bonding pads further comprises exposing the solder ball pads by removing a part of the first insulation layer or a part of the second insulation layer which correspond to the location of the solder ball pads.

3. The method of claim 1, wherein the forming of the circuit pattern further comprises:
laminating a seed layer onto a carrier board;
forming the circuit pattern on the seed layer;
laminating the first insulation layer onto the carrier board such that the circuit pattern is embedded in the first insulation layer; and
removing the carrier board and the seed layer.

4. The method of claim 1, wherein the first insulation layer and the second insulation layer include a photoresist material, and the exposing of the bonding pads comprises removing a the part of the first insulation layer and the part of the second insulation layer by exposure and development.

5. A printed circuit board for an electronic component package, the printed circuit board comprising:
a first insulation layer;
a circuit pattern laminated on one side of the first insulation layer and comprising bonding pads and solder ball pads;
a second insulation layer laminated on the one side of the first insulation layer;
a cavity, formed in correspondence with the location of the bonding pads and the solder ball pads for exposing the bonding pads and the solder ball pads, and formed by removing a part of the first insulation layer and a part of the second insulation layer.

6. The printed circuit board of claim 5, wherein the first insulation layer and the second insulation layer are photosensitive.
